(19) United States
(12) Patent Application Publication
(10) Pub. No.: US 2004/0245542 A1
(43) Pub. Date: Dec. 9, 2004

(54) Organic light-emitting device having high luminescent efficiency

(76) Inventor: Hae-Won Kim, Kyonggi-Do (KR)

Correspondence Address: ST. ONGE STEWARD JOHNSTON & REENS, LLC, 986 BEDFORD STREET, STAMFORD, CT, 06905-5619, US

(21) Appl. No.: 10/830,256

(22) Filed: Apr. 22, 2004

(30) Foreign Application Priority Data
Nov. 12, 2001 (KR) 2001-70024
Oct. 30, 2002 (WO) PCT/KR02/02021

(51) Int. Cl. H01L 33/00

(52) U.S. Cl. 257/103

(57) ABSTRACT

An organic light-emitting device (OLED) having high luminescent efficiency in which most electrons and holes are combined within a light-emitting layer of the OLED is disclosed. The OLED comprises a first electrode formed on a substrate, at least one organic layer including an organic light-emitting layer, a second electrode formed on the organic layer, a hole inducing layer including a material having an ionization potential higher than that of the organic light-emitting layer and formed between the first electrode and the organic light-emitting layer and/or an electron blocking layer including a material having an electron affinity higher than that of the organic light-emitting layer and formed between the second electrode and the organic light-emitting layer.

### FIELD OF THE INVENTION

The present invention relates to an organic light-emitting device (OLED) having high luminescent efficiency and, more particularly, to an OLED having high luminescent efficiency and long lifetime in which most holes and electrons are combined in a light-emitting layer of the OLED.

### BACKGROUNDS OF THE INVENTION

Generally, an OLED has a transparent anode, a metal cathode and a light-emitting layer including a low molecular or polymeric luminescent organic compound and formed between the anode and the cathode. When a voltage is applied between the anode and the cathode, light is radiated from the light-emitting layer. The OLED has not only a fast response speed but also an excellent brightness and wide viewing angle. Also, the OLED has advantages that the OLED operates with a low driving voltage, and full colors in a visible region can be displayed, and it does not need a backlight for light-emitting due to its self-light emitting property. In addition, the OLED can be manufactured into a thin film and flexible type device, and can be mass-produced by well-known film fabrication techniques.

FIG. 1 shows a cross sectional view of a conventional OLED. As shown in FIG. 1, the OLED includes the first electrode 12 (anode), at least one organic light-emitting layer 20 formed on the first electrode 12, and the second electrode 22 (cathode) formed on the light-emitting layer 20 while facing the first electrode 12. Conventionally, the first electrode 12 is made of materials having a high work function, for example, Indium Tin Oxide, polyaniline and Ag, and the second electrode 22 is made of materials having a low work function (generally, less than 4 eV), for example, Al, Mg—Ag, Li, and Ca. The organic light-emitting layer 20 is composed of an organic luminescent single compound or a conjugated polymer. In addition, a hole injecting layer 14 and a hole transporting layer 16 can be provided between the first electrode 12 and the light-emitting layer 20 to facilitate hole injection and transportation. The hole injecting layer 14 is made of materials having an ionization potential higher than that of the anode and lower than that of the light-emitting layer 20, and the hole transporting layer 16 is made of materials having an ionization potential higher than that of the hole injecting layer 14 and lower than that of the light-emitting layer 20. Also, an electron injecting layer 24 and an electron transporting layer 26 can be generally provided between the second electrode 22 and the light-emitting layer 20 to facilitate electron injection and transportation. The electron injecting layer 24 is made of materials having work function higher than that of the cathode 22 and an electron affinity lower than that of the electron transporting layer 26, and the electron transporting layer 26 is made of materials having an electron affinity higher than that of the electron injecting layer 24 and lower than that of the light-emitting layer 20.

In operation, the hole and the electron are produced at the anode 12 and the cathode 16 by applying a voltage. The produced hole and the electron are injected into the light-emitting layer 20 via the hole injecting layer 14, the hole transporting layer 16, the electron injecting layer 24 and the electron transporting layer 26. The injected holes and the electrons are recombined in the light-emitting layer 20, which induces light radiation, and the radiated light is displayed through the anode 12 and a substrate 10 made of optically transparent material.

Amount of holes and electrons injected to the light-emitting layer 20 can be adjusted by modifying the thickness of the hole injecting layer 14, the hole transporting layer 16, the electron injecting layer 24 or the electron transporting layer 26 or by modifying the materials composing the layers. However, it is generally difficult to precisely control the thickness of each layer in a large-size OLED. In addition, as the voltage applied between the anode 12 and the cathode 22 increases, the amount of the injected electrons increases. In this case, a part of the injected electrons passes through the light-emitting layer 20, and is extinguished in a layer other than the light-emitting layer 20. Thus, the part of the electron cannot used for light-emitting, which deteriorates the luminescent efficiency of the OLED.

### SUMMARY OF THE INVENTION

It is an object of the present invention to provide an OLED having high luminescent efficiency in which most electrons and holes are combined within a light-emitting layer of the OLED.

It is another object of the present invention to improve the luminescent efficiency of an OLED, thereby to increase the life-time of the OLED.

To accomplish these objects, the present invention provides an OLED comprising a first electrode formed on a substrate, at least one organic layer including an organic light-emitting layer, a second electrode formed on the organic layer, a hole inducing layer including a material having an ionization potential higher than that of the organic light-emitting layer and formed between the first electrode and the organic light-emitting layer and/or an electron blocking layer including a material having an electron affinity higher than that of the organic light-emitting layer and formed between the second electrode and the organic light-emitting layer.

Preferably, the hole inducing layer is interposed between a hole transporting layer formed on the first electrode and the light-emitting layer, and the electron blocking layer is interposed between an electron transporting layer formed on the light-emitting layer and the light-emitting layer. Alternatively, the hole inducing layer and the electron blocking layer may be formed by being mixed with the hole transporting layer and the electron transporting layer, respectively.

### BRIEF DESCRIPTION OF THE DRAWINGS

A more complete appreciation of the invention, and many of the attendant advantages thereof, will be readily apparent by reference to the following detailed description when considered in conjunction with the accompanying drawings in which like reference numerals indicate the same or the similar components, wherein:

FIG. 1 is a cross sectional view of a conventional OLED;

FIG. 2 is a cross sectional view of an OLED according to an embodiment of the present invention;

FIGS. 3a and 3b are energy band diagrams of OLEDs according to a conventional art and an embodiment of the present invention, respectively;

FIGS. 4a and 4b are graphs showing the relationship of an applied voltage vs. a current density and a brightness of OLEDs according to a conventional art and an embodiment of the present invention, respectively; and

FIGS. 5a and 5b are graphs showing a relationship of an applied voltage vs. a luminescent efficiency of the OLEDs according to a conventional art and an embodiment of the present invention, respectively.

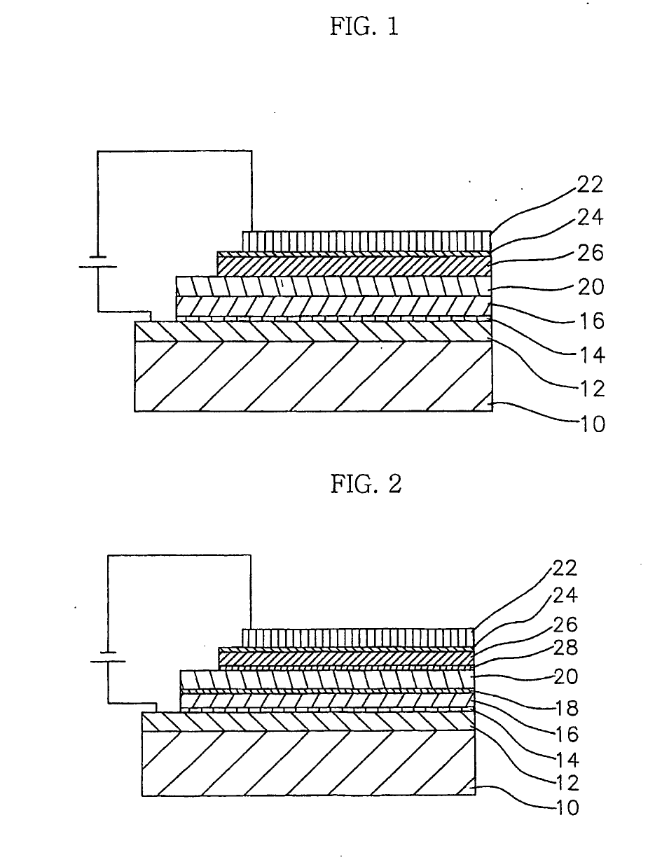

### DETAILED DESCRIPTION OF THE INVENTION

FIG. 2 is a cross sectional view of an OLED according to an embodiment of the present invention. As shown in FIG. 2, the OLED according to the present invention radiates light by interposing a light emitting organic material between two electrodes, and applying an operation voltage between the electrodes. One of the two electrodes must be transparent for transmission of the radiated light.

As shown in FIG. 2, the OLED according to an embodiment of the present invention includes an anode 12, a hole injecting layer 14, a hole transporting layer 16, a hole inducing layer 18, a light-emitting layer 20, an electron blocking layer 28, an electron transporting layer 26, an electron injecting layer 24 and a cathode 22, which are successively formed on a substrate 10. The hole injecting layer 14 and the electron injecting layer 24 can be optionally formed in accordance with the structure of the OLED.

The hole inducing layer 18 may be formed by doping or depositing a material having an ionization potential higher than that of the light-emitting layer 20 on the hole transporting layer 16. Alternatively, the hole inducing layer 18 may be formed in the hole transporting layer 16 in a mixed form by mixing the material for producing the hole inducing layer 18 with the material for producing the hole transporting layer 16 and then depositing them. In this case, the hole inducing layer's practical thickness can be 0 to 500 Å, preferably 1 to 100 Å.

In order to control amount of electrons injected to the light-emitting layer 20, the electron blocking layer 28 may be formed by doping or depositing a material having an electron affinity higher than that of the light-emitting layer 20 on the light-emitting layer 20. Alternatively, the electron blocking layer 28 may be formed in the electron transporting layer 26 in a mixed form by mixing the material for producing the electron blocking layer 18 with the material for producing the electron transporting layer 26 and then depositing them. In this case, the electron blocking layer's practical thickness can be 0 to 500 Å, preferably 1 to 100 Å.

In the OLED according to the present invention, the hole inducing layer 18 is formed with a material having an ionization potential higher than that of the light-emitting layer 20, that is, with a material having a HOMO energy level lower than that of the light-emitting layer 20. Thus, the electrons in the light-emitting layer 20 can be inductively injected to the hole inducing layer 18. Thereby the hole density of the light-emitting layer 20 increases, and the luminescent efficiency of the OLED increases. The electron blocking layer 28 is formed with a material having an electron affinity higher than that of the light-emitting layer 20, that is, with a material having a LUMO energy level higher than that of the light-emitting layer 20. Thus, the amount of the electrons injected into the light-emitting layer 20 can be controlled by the electron blocking layer 28. Therefore, the amount of the electrons and amount of the holes injected to the light-emitting layer 20 can be balanced, and the possibility for recombination of the electrons and the holes in the light-emitting layer 20 increases, and the luminescent efficiency of the OLED increases. Though the OLED of FIG. 2 includes both the hole inducing layer 18 and the electron blocking layer 28, the OLED according to the present invention can include one of the two layers.

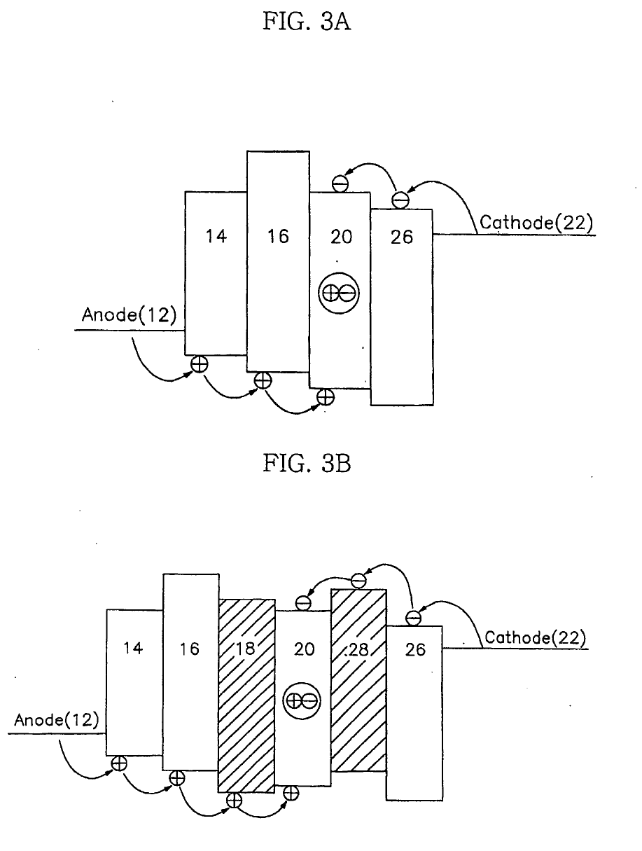

The energy band diagrams of OLEDs according to a conventional art and an embodiment of the present invention are shown in FIGS. 3a and 3b, respectively. The reference numeral depicted in an energy band in FIGS. 3a and 3b indicates that the energy band is the energy band of the layer in FIG. 2 to which same reference numeral are designated. As shown in FIG. 3A, the ionization potentials of the anode 12, the hole injecting layer 14, the hole transporting layer 16, and the light-emitting layer 20 of the conventional OLED gradually increases to naturally induce the hole into the light-emitting layer 20, and the electron affinities of the cathode 14, the electron injecting layer 24, the electron transporting layer 26, and the light-emitting layer 20 of the conventional OLED gradually increases to naturally induce the electron into the light-emitting layer 20.

In contrast, in the OLED according to an embodiment of the present invention shown in FIG. 3b, the electron blocking layer 28 having the electron affinity higher than that of the light-emitting layer 20 is formed between the electron transporting layer 26 and the light-emitting layer 20, to control the amount of the electrons injected to the light-emitting layer 20. In addition, the hole inducing layer 18 having the ionization potential higher than that of the light-emitting layer 20 is provided between the hole transporting layer 16 and the light-emitting layer 20, to increase the hole density of the light-emitting layer 20.

In the present invention, the anode 12 can be made of materials having a high work function, for example, Indium Tin Oxide(ITO), polyaniline and Ag, and the cathode 22 can be made of materials having a low work function, for example, Al, Mg—Ag, Li, and Ca. The organic light-emitting layer 20 can be made of various conventional organic compounds under the condition that the organic compounds satisfy the above-described energy relationship with the materials for producing the hole inducing layer 18 and/or the electron blocking layer 28. Examples of the organic compounds for producing the organic light-emitting layer 20 include tris(8-quinolinolate)aluminum (Alq₃), 10-benzo[h]quinolinol-beryllium complex (BeBq₂) or tris(4-methyl-8-quinolinolate)aluminum (Almq), which emits green light (550 nm). Examples of the blue (460 nm) luminescent single compound include a metal complex such as Bis[2-(2-benzoxazolyl)phenolato]Zinc(II) (ZnPBO) or Bis(2-methyl-8-quinolinolato)(para-phenyl-phenolato)aluminum (Balq) or an organic compound such as strylarylene derivatives, 4,4′-bis(2,2′-biphenylvinyl)-1,1′-biphenyl (DPVBi), oxadiazole derivatives or bisstrylanthracene-based derivatives such as 4,4′-Bis((2-carbazole)vinylene)biphenyl (BczVBi). Examples of the red (590 nm) luminescent organic compound include 4-(dicyanomethylene)-2-methyl-6-(p-dimethylaminostyryl)-4H-pyran (DCM) or DCM-based 4-dicyanomehtlyene-6-cp-julolidinostyrl-2-tert-butyl-4H-pyran (DCJTB). Besides these compounds, various other organic compounds or conjugated oligomers or polymers can be used to form the light-emitting layer 20. In addition, a host material having good electron/hole mobility and the luminescent efficiency and a dopant having various colors can be mixed to form the light-emitting layer 20, which generally called as a guest-host doping system.

Examples of materials to form the hole injecting layer 14 and the hole transporting layer includes porphyrinic compound such as copper phthalocyanine (CuPc, See U.S. Pat. No. 4,356,429), tri(phenyldiamine) derivatives such as N,N′-diphenyl-N,N′bis(3-methylphenyl)-[1,1′-biphenyl]-4,4′-diamine (TPD), 4,4′,4″-tris[3-methylphenyl(phenyl)amino]triphenylamine (m-MTDATA), N,N′-diphenyl-N,N′-bis(1-napthtylphenyl)-1,1′-biphenyl-4,4′-diamine (α-NPD), N,N,N′N′-tetrakis(m-methylphenyl)-1,3-diaminobenzene (PDA), 1,1-bis[N,N-di(p-tolyl)aminophenyl]cyclohexane (TPAC), strylamine derivatives and amine derivatives having fused aromatic ring such as N,N′-bis(1-naphthyl)-N,N′-diphenyl-benzidin. Examples of materials to form the electron injecting layer 24 and the electron transporting layer 26 include LiF, 1,2,4-triazole (TAZ), quinoline derivatives and Alq₃. The materials to form the hole inducing layer 18 or the electron blocking layer 28 can include the materials to form the hole injecting layer 14, the hole transporting layer 16, the electron injecting layer 24 and the electron transporting layer 26 under the condition that the materials for producing the hole inducing layer 18 and/or the electron blocking layer 28 satisfy the above-described energy relationship with the material for producing the light-emitting layer 20. The hole inducing layer 18 and/or the electron blocking layer 28 can be made of one or more materials, if necessary to satisfy the above-described energy relationship. Layers including the hole inducing layer 18 and the electron blocking layer 28 can be prepared by various conventional methods such as a spin-coating method, a thermal evaporation, a spin-casting method, a sputtering method, an electron-beam evaporation, and a chemical vapor deposition (CVD). Alternatively, two or more materials for producing the layers can be co-deposited by the above-mentioned methods. The anode 12 and the cathode 22 can be prepared by a conventional method such as a sputtering method, an ion plating method, a thermal or electron-beam evaporation, or a chemical vapor deposition. The thickness of the organic layers are not specifically restricted and can be determined according to the operation condition and the structure of the desired OLED. However, It is preferred that the thickness of each layer is within the range of from 5 nm to 500 nm.

Hereinafter, the present invention will be explained in detail with reference to an example and a comparative example.

### EXAMPLE

An Indium Tin oxide (ITO) coated glass substrate was ultrasonically washed and then washed with deionized water. The grease on the washed substrate was removed with gas phase toluene, and dried. To produce an OLED, a hole injection layer of thickness of 400 Å was formed by vacuum depositing m-MTDATA on the ITO layer, and a hole transporting layer of thickness of 300 Å was formed by vacuum depositing α-NPD on the hole injection layer. Then, the mixture of α-NPD and TAZ was vacuum deposited on the hole transporting layer to form a hole inducing layer of the thickness of about 200 Å. The weight ratio of α-NPD:TAZ can be 1:0.5-1.5, and the ratio was 1:1 in this example. As the organic luminescent compound, Alq3 was vacuum deposited to a thickness of 600 Å to form the organic light-emitting layer. Then, TAZ(3-(4-Biphenyl)-4-phenyl-5-tert-butylphenyl)-1,2,4-triazole) was vacuum deposited to a thickness of 380 Å to form an electron transporting layer on the organic light-emitting layer, and LiF of thickness of 7 Å and Ag of thickness of 2000 Å were subsequently deposited on the electron transporting layer to form an electron injection layer and a cathode.

### Comparative Example

Except for not depositing the mixture of α-NPD and TAZ for forming the hole inducing layer, an OLED was manufactured according to the method described in the above Example.

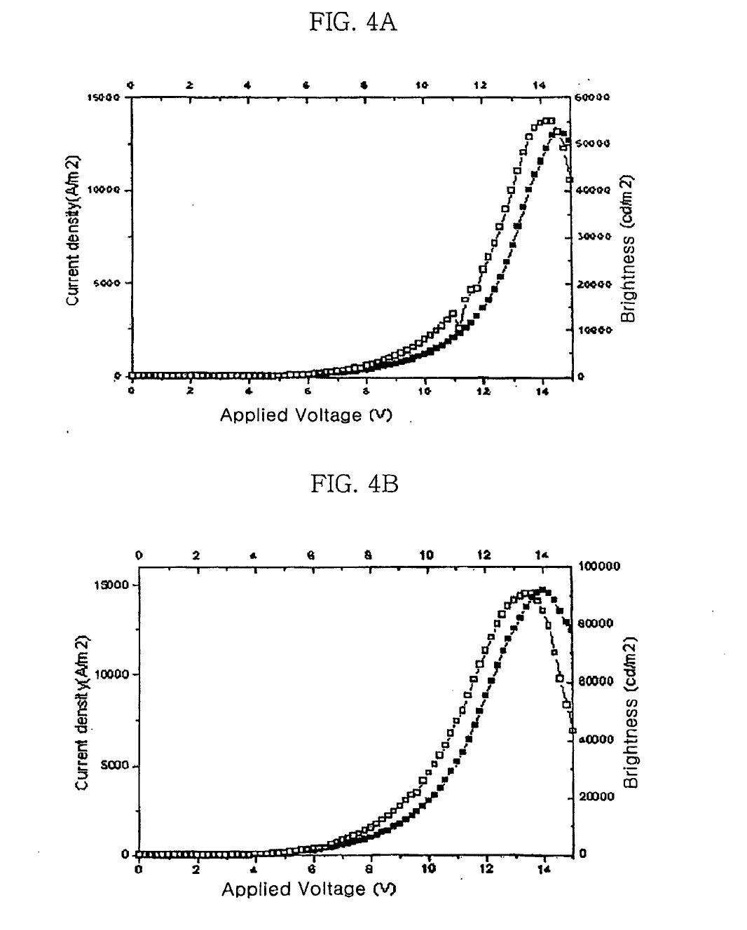

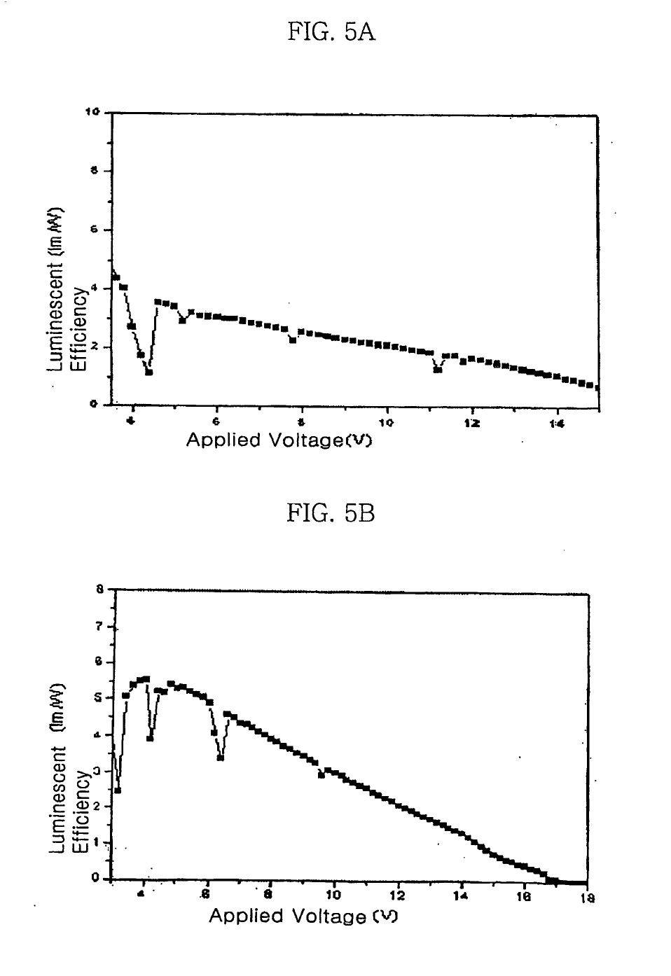

The relationship of an applied voltage vs. a current density and a brightness of the OLEDs according to the Comparative Example and the Example were measured, and shown in FIGS. 4a and 4b, respectively. In FIGS. 4A and 4B, the symbol “ [symbol] ” stands for the brightness and the symbol “▪” stands for the current density. As shown in FIGS. 4a and 4b, the brightness of the OLED of the Example (FIG. 4B) is very high in comparison with that of the OLED of the Comparative Example (FIG. 4A). The relationship of an applied voltage vs. a luminescent efficiency of the OLEDs according to the Comparative Example and the Example were measured, and shown in FIGS. 5a and 5b, respectively. The luminescent efficiency η was calculated by the equation η=π×L/[V×J], wherein L represents a brightness, V represents an applied voltage, and J represents a current density. As shown in FIGS. 5a and 5b, the luminescent efficiency of the OLED of the Example (FIG. 5B) is very high in comparison with that of the OLED of the Comparative Example (FIG. 5A), especially at low applied voltage.

In the OLED of the present invention, the material having the ionization potential higher than that of the light-emitting layer 20 is incorporated between the anode 12 and the light-emitting layer 20, which induces the hole generation and increases the hole density in the light-emitting layer 20. Also, the material having the electron affinity higher than that of the light-emitting layer 20 is incorporated between the cathode 22 and the light-emitting layer 20, which controls or decreases the amount of the injected electrons, and minimizes the number of electrons extinguished in a layer other than the light-emitting layer 20. Therefore, the possibility for recombination of the electrons and the holes in the light-emitting layer 20 increases, and the luminescent efficiency and the life time of the OLED increases.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. An organic light-emitting device comprising:
a first electrode formed on a substrate;
at least one organic layer including an organic light-emitting layer formed on the first electrode;
a second electrode formed on the organic layer; and
a hole inducing layer including a material having an ionization potential higher than that of the organic light-emitting layer and formed between the first electrode and the organic light-emitting layer and/or an electron blocking layer including a material having an electron affinity higher than that of the organic light-emitting layer and formed between the second electrode and the organic light-emitting layer.

2. The organic light-emitting device according to claim 1, further comprising a hole transporting layer formed on the first electrode.

3. The organic light-emitting device according to claim 2, wherein the hole inducing layer is formed between the hole transporting layer and the organic light-emitting layer.

4. The organic light-emitting device according to claim 2, wherein the hole inducing layer is formed by being mixed with the hole transporting layer.

5. The organic light-emitting device according to claim 1, further comprising an electron transporting layer formed on the light-emitting layer.

6. The organic light-emitting device according to claim 5, wherein the electron blocking layer is formed between the electron transporting layer and the organic light-emitting layer.

7. The organic light-emitting device according to claim 5, wherein the electron blocking layer is formed by being mixed with the electron transporting layer.

8. The organic light-emitting device according to claim 1, further comprising a hole injecting layer on the first electrode, and an electron injecting layer under the second electrode.

9. The organic light-emitting device according to claim 1, wherein the first electrode is made of ITO, the second electrode is made of Ag, the hole inducing layer includes the mixture of α-NPD and TAZ and the organic light-emitting layer is made of Alq3.

10. The organic light-emitting device according to claim 9, further comprising a hole injecting layer formed on the first electrode and comprising m-MTDATA, a hole transporting layer formed on the hole injecting layer and comprising α-NPD, and wherein the hole inducing layer is formed on the hole transporting layer and made of the mixture of α-NPD and TAZ.
